(19) United States
(12) Patent Application Publication
(10) Pub. No.: US 2025/0291972 A1
(43) Pub. Date: Sep. 18, 2025

(54) DISCOVERY OF POWER-SYSTEM PROJECTS

(71) Applicant: BootstrapLab, LLC, San Francisco, CA (US)

(72) Inventors: Lars Vinberg, Mountain View, CA (US); Nicolai Daniel Wadstrom, Redwood City, CA (US); Erik Nils Stark, Malmö (SE); Thomas Andrew Campbell, Evergreen, CO (US); Fabio Ficano, San Francisco, CA (US); Björn Smedman, Malmö (SE); Daniel C Riedel, San Francisco, CA (US); Shmuel Silverman, Novato, CA (US)

(73) Assignee: BootstrapLab, LLC, San Francisco, CA (US)

(21) Appl. No.: 19/076,877

(22) Filed: Mar. 11, 2025

Related U.S. Application Data
(60) Provisional application No. 63/564,144, filed on Mar. 12, 2024.

(51) Int. Cl. G06F 30/20

(52) U.S. Cl. CPC G06F 30/20

(57) ABSTRACT

A computer system (which may include one or more computers) that identifies a plan for a power-system project is described. During operation, the computer system may access stored information that specifies plans for power-system projects. Then, based at least in part on the information, the computer system may estimate risks and/or ROIs for the power-system projects. Moreover, based at least in part on the estimated risks and/or ROIs, the computer system may identify the plan for the power-system project in the plans for the power-system projects. Next, the computer system may provide second information specifying the identified plan for the power-system project.

### CROSS REFERENCE TO RELATED APPLICATIONS

This application claims priority under 35 U.S.C. 119(e) to U.S. Provisional Application Ser. No. 63/564,144, entitled “Discovery of Power-System Projects,” by Fabio Ficano, filed on Mar. 12, 2024, the contents of both of which are herein incorporated by reference.

### FIELD

The described embodiments relate to discovery of power-system projects.

### BACKGROUND

Power systems are complicated networks that deliver electricity from generation sources to consumers. Assessments (such as planning and forecasting) of potential projects for power systems typically involves analyzing the current and future demand (or load), the supply, reliability, and economics of the proposed power system, as well as the associated environmental and social impacts. In general, projects for centralized power systems are usually large and, consequently, expensive, costing in excess of $100 M. However, because of the high costs, utilities are often able to absorb or incorporate the current large costs that occur when performing assessments for such projects.

In contrast, distributed power systems (such as miniature power plants) typically involve smaller projects and, consequently, lower costs. This reduction in scale reduces the associated risks and often facilitates the use of more environmentally friendly technologies, such as renewable energy. However, the lower overall costs make it difficult to amortize the overhead associated with existing project assessments, thereby making it harder to obtain approval for potential projects in distributed power systems.

### SUMMARY

In a first group of embodiments, a computer system (which may include one or more computers) that automatically generates a plan for a power-system project is described. This computer system includes: a computation device; and memory that stores program instructions. When executed by the computation device, the program instructions cause the computer system to perform one or more operations. Notably, during operation of the computer system, the computer system accesses (or obtains) stored information, where the stored information includes: wind data, solar data, ownership of land, energy cost, environmental conditions, connectivity, local infrastructure, regulations associated with a utility approval process, and available equipment (such as wind and/or solar, e.g., photo-voltaic equipment). Then, based at least in part on the information, the computer system automatically generates the plan for the power-system project. Moreover, the computer system provides second information specifying the plan for the power-system project.

Note that the power-system project may have a cost that is less than a predefined amount. For example, the predefined amount may be $2 M.

Moreover, a second cost of generating the plan may be less than a second predefined amount, such as 10% of the predefined amount.

Furthermore, the power-system project may include a distributed power-system project that is located at multiple locations in a region (as opposed to at a centralized location).

Additionally, the information may be accessed in a database, and the information may be stored in a directed graph.

In some embodiments, the computer system may compute an estimate of a return on investment (ROI) for the power-system project, and the computer system may select the power-system project based at least in part on the estimated ROI.

Note that the plan may be generated using a pretrained large-language model (LLM). More generally, the plan may be generated using a pretrained neural network. In some embodiments, the selecting and/or the generating are performed using a digital twin that provides a virtual representation of the power-system project.

Moreover, the computer system may determine an estimated risk associated with the power-system project, and the computer system selects the power-system project based at least in part on the estimated risk.

Furthermore, providing the second information may include: storing the second information in a computer-readable memory; displaying the second information on a display; and/or printing the second information on paper.

Additionally, automatically generating the plan may include submitting the plan and receiving feedback about the plan during an approval process associated with a regulator of a utility or a power system and/or a municipal government, and, as needed, automatically and iteratively updating the plan based at least in part on the feedback between at least a pair of steps in the approval process.

Another embodiment provides a computer for use, e.g., in the computer system.

Another embodiment provides a computer-readable storage medium for use with the computer or the computer system. When executed by the computer or the computer system, this computer-readable storage medium causes the computer or the computer system to perform at least some of the aforementioned operations.

Another embodiment provides a method, which may be performed by the computer or the computer system. This method includes at least some of the aforementioned operations.

In a second group of embodiments, a computer system (which may include one or more computers) that identifies a plan for a power-system project is described. This computer system includes: a computation device; and memory that stores program instructions. When executed by the computation device, the program instructions cause the computer system to perform one or more operations. Notably, during operation of the computer system, the computer system accesses (or obtains) stored information that specifies plans for power-system projects. Then, based at least in part on the information, the computer system estimates risks and/or return on investments (ROIs) for the power-system projects. Moreover, based at least in part on the estimated risks and/or ROIs, the computer system identifies the plan for the power-system project in the plans for the power-system projects. Next, the computer system provides second information specifying the identified plan for the power-system project.

Note that the power-system project may have a cost that is less than a predefined amount. For example, the predefined amount may be $2 M.

Moreover, the power-system project may include a distributed power-system project that is located at multiple locations in a region (as opposed to at a centralized location).

Furthermore, the information may be accessed in a database, and the information may be stored in a directed graph.

Additionally, based at least in part on an ordinance change associated with a municipal government or a regulator of a utility, the computer system may automatically modify the plan for the power system project, where the modified plan decreases an estimated risk of the power-system project and/or increases an estimated ROI of the power-system project. Note that the plan may be modified using a pretrained LLM. More generally, the plan may be modified using a pretrained neural network. In some embodiments, the modifying is performed using a digital twin that provides a virtual representation of the power-system project.

Moreover, providing the second information may include: storing the second information in a computer-readable memory; displaying the second information on a display; and/or printing the second information on paper.

Furthermore, the computer system may automatically submit the identified plan and receive feedback about the plan during an approval process associated with a utility commission and/or a municipal government. As needed, the computer system may automatically and iteratively update the plan based at least in part on the feedback between at least a pair of steps in the approval process.

Additionally, identifying the plan may include: presenting (e.g., in a user interface) the plans for the power-system projects and associated estimated risks and/or ROIs; and receiving a user selection of the plan for the power-system project. Alternatively, the computer system may automatically identify the plan.

Another embodiment provides a computer for use, e.g., in the computer system.

Another embodiment provides the user interface for use, e.g., in the computer system.

Another embodiment provides a computer-readable storage medium for use with the computer or the computer system. When executed by the computer or the computer system, this computer-readable storage medium causes the computer or the computer system to perform at least some of the aforementioned operations.

Another embodiment provides a method, which may be performed by the computer or the computer system. This method includes at least some of the aforementioned operations.

In a third group of embodiments, a computer system (which may include one or more computers) that modifies a plan for a power-system project is described. This computer system includes: a computation device; and memory that stores program instructions. When executed by the computation device, the program instructions cause the computer system to perform one or more operations. Notably, during operation of the computer system, the computer system accesses (or obtains) stored information that specifies the plan for the power-system project and second information specifying prior power-system projects that were successful. Then, the computer system submits the plan and receives feedback about the plan during an approval process associated with a utility commission and/or a municipal government. Moreover, based at least in part on the second information and the feedback, the computer system automatically modifies the plan for the power-system project, where the modified plan increases an estimated probability of success of the power-system project. Next, the computer system provides third information specifying the modified plan for the power-system project.

Note that the power-system project may have a cost that is less than a predefined amount. For example, the predefined amount may be $2 M.

Moreover, the power-system project may include a distributed power-system project that is located at multiple locations in a region (as opposed to at a centralized location).

Furthermore, the information and/or the second information may be accessed in a database, and the information may be stored in a directed graph.

In some embodiments, the computer system may compute an estimate of an ROI for the power-system project, and the plan may be modified based at least in part on the estimated ROI. Note that the plan may be modified using a pretrained LLM. More generally, the plan may be modified using a pretrained neural network. In some embodiments, the modifying is performed using a digital twin that provides a virtual representation of the power-system project.

Moreover, the computer system may determine an estimated risk associated with the power-system project, and the plan may be modified based at least in part on the estimated risk.

Furthermore, providing the third information may include: storing the third information in a computer-readable memory; displaying the third information on a display; and/or printing the third information on paper.

Note that modifying the plan may include changing one or more parameters in the plan based at least in part on parameters associated with at least one of the prior power-system projects.

Another embodiment provides a computer for use, e.g., in the computer system.

Another embodiment provides a computer-readable storage medium for use with the computer or the computer system. When executed by the computer or the computer system, this computer-readable storage medium causes the computer or the computer system to perform at least some of the aforementioned operations.

Another embodiment provides a method, which may be performed by the computer or the computer system. This method includes at least some of the aforementioned operations.

This Summary is provided for purposes of illustrating some exemplary embodiments, so as to provide a basic understanding of some aspects of the subject matter described herein. Accordingly, it will be appreciated that the above-described features are examples and should not be construed to narrow the scope or spirit of the subject matter described herein in any way. Other features, aspects, and advantages of the subject matter described herein will become apparent from the following Detailed Description, Figures, and Claims.

### BRIEF DESCRIPTION OF THE FIGURES

FIG. 1 is a block diagram illustrating an example of a computer system in accordance with an embodiment of the present disclosure.

FIG. 2 is a drawing illustrating an example of a portion of a directed graph in accordance with an embodiment of the present disclosure.

FIG. 3 is a flow diagram illustrating an example of a method for automatically generating a plan for a power-system project using a computer system in FIG. 1 in accordance with an embodiment of the present disclosure.

FIG. 4 is a drawing illustrating an example of communication between components in a computer system in FIG. 1 in accordance with an embodiment of the present disclosure.

FIG. 5 is a flow diagram illustrating an example of a method for identifying a plan for a power-system project using a computer system in FIG. 1 in accordance with an embodiment of the present disclosure.

FIG. 6 is a drawing illustrating an example of communication between components in a computer system in FIG. 1 in accordance with an embodiment of the present disclosure.

FIG. 7 is a drawing illustrating an example of a user interface associated with a computer in FIG. 1 in accordance with an embodiment of the present disclosure.

FIG. 8 is a flow diagram illustrating an example of a method for modifying a plan for a power-system project using a computer system in FIG. 1 in accordance with an embodiment of the present disclosure.

FIG. 9 is a drawing illustrating an example of communication between components in a computer system in FIG. 1 in accordance with an embodiment of the present disclosure.

FIG. 10 is a block diagram illustrating an example of a neural network in accordance with an embodiment of the present disclosure.

FIG. 11 is a block diagram illustrating an example of a computer in a computer system in FIG. 1 in accordance with an embodiment of the present disclosure.

Note that like reference numerals refer to corresponding parts throughout the drawings. Moreover, multiple instances of the same part are designated by a common prefix separated from an instance number by a dash.

### DETAILED DESCRIPTION

In a first group of embodiments, a computer system (which may include one or more computers) that automatically generates a plan for a power-system project is described. During operation, the computer system may receive a user query that specifies an objective or a goal. Then, the computer system may access stored information, where the stored information includes: wind data, solar data, ownership of land, energy cost, environmental conditions, connectivity, local infrastructure, regulations associated with a utility approval process, and available equipment (such as wind and/or solar equipment). Next, based at least in part on the information and the objective or goal, the computer system may automatically generate the plan for the power-system project. Moreover, the computer system may provide second information specifying the plan for the power-system project.

By automatically generating the plan, the project-management techniques may significantly decrease the cost of preparing proposals and obtaining approval from municipalities and regulators for power-system projects. For example, the cost may be reduced by at least 90%. This may allow smaller power-system projects (such as those with a cost less than $2 M) to be pursued. Notably, the project-management techniques may allow power systems to pursue distributed power-system projects (as opposed to centralized power-system projects, which typically cost at least $100 M). By automating the process of preparing plans for power-system projects, the project-management techniques may allow renewable energy projects to be pursued and approved. Thus, the project-management techniques may make the power companies more flexible and allow them to implement power-system projects that more effectively address the challenges posed by climate change.

In a second group of embodiments, a computer system (which may include one or more computers) that identifies a plan for a power-system project is described. During operation, the computer system may access stored information that specifies plans for power-system projects. Then, based at least in part on the information, the computer system may estimate risks and/or ROIs for the power-system projects. Moreover, based at least in part on the estimated risks and/or ROIs, the computer system may identify the plan for the power-system project in the plans for the power-system projects. Next, the computer system may provide second information specifying the identified plan for the power-system project.

By identifying the power-system project, the power-management techniques may allow power companies to discover and repurpose plans for power-system projects. For example, the power-management techniques may adapt an existing plan for a power system to address an ordinance change implemented by a regulator of a utility and/or a municipality. Thus, the project-management techniques may make the power companies more flexible and may allow them to obtain approval for power-system projects. These capabilities may reduce the cost associated with the planning and review of proposals for power-system projects, which may enable smaller power-system projects (such as those with a cost less than $2 M), such as distributed power-system projects (e.g., renewable energy projects). Consequently, the project-management techniques may allow power companies to more effectively address the challenges posed by climate change.

In a third group of embodiments, a computer system (which may include one or more computers) that modifies a plan for a power-system project is described. During operation, the computer system may access stored information that specifies the plan for the power-system project and second information specifying prior power-system projects that were successful. Then, the computer system may submit the plan and may receive feedback about the plan during an approval process associated with a utility commission and/or a municipal government. Moreover, based at least in part on the second information and the feedback, the computer system may automatically modify the plan for the power-system project, where the modified plan increases an estimated probability of success of the power-system project. Next, the computer system may provide third information specifying the modified plan for the power-system project.

By modifying the plan for the power-system project, the power-management techniques may allow power companies to automate the process of obtaining approval for the power-system project from a regulator of a utility or power system and/or a municipality. Moreover, by allowing the power system to perform these operations at scale, the power-management techniques may significantly reduce the cost of developing and obtaining approval for power-system projects. These capabilities may allow the power system to effectively pursue smaller power-system projects (such as those with a cost less than $2 M), such as distributed power-system projects (e.g., renewable energy projects). Consequently, the project-management techniques may make the power companies more flexible and may allow them to pursue distributed power-system projects (e.g., renewable energy projects). Consequently, the project-management techniques may allow power companies to more effectively address the challenges posed by climate change.

In the discussion that follows, the project-management techniques may use a pretrained neural networks, such as an LLM or a transformer model (which performs natural language processing to translate, predict and generate natural language, such as text or speech). For example, the transformer model may include a Generative Pre-Trained Transformer, such as ChatGPT (from OpenAI, Inc. of San Francisco, California). More generally, the pretrained neural network may include a wide variety of neural network architectures and configurations, including: a convolutional neural network, a recurrent neural network, an autoencoder neural network, a perceptron neural network, a feed forward neural network, a radial basis neural network, a deep feed forward neural network, a long/short term memory neural network, a gated recurrent unit neural network, a variational autoencoder neural network, a denoising neural network, a sparse neural network, a Markov chain neural network, a Hopfield neural network, a Boltzmann machine neural network, a restricted Boltzmann machine neural network, a deep belief neural network, a deep convolutional neural network, a deconvolutional neural network, a deep convolutional inverse graphics neural network, a generative adversarial neural network, a liquid state machine neural network, an extreme learning machine neural network, an echo state neural network, a deep residual neural network, a Kohonen neural network, a support vector machine neural network, a neural turing machine neural network, or another type of neural network (which may, at least, include: an input layer, one or more hidden layers, and an output layer).

In general, the pretrained neural network may use information specifying project information as inputs and may output second information specifying a modified or a generated plan for a power-system project. For example, the project information may include: wind data, solar data, ownership of land, energy cost, environmental conditions, connectivity, local infrastructure, regulations associated with a utility approval process, and available equipment (such as wind and/or solar equipment). More generally, the information input to the pretrained neural network (and, more generally, a machine-learning model) may include: audio, sound, acoustic data (such as ultrasound or seismic measurements), radar data, images (such as an image in the visible spectrum, an infrared image, an ultraviolet image, etc.), video, classifications, speech or speech-recognition data, object-recognition data, computer-vision data, environmental data (such as data corresponding to temperature, humidity, barometric pressure, wind direction, wind speed, sunlight, shade, weather, etc.), one or more proposed locations, estimated energy load or demand, available renewal-energy resources at or proximate to the one or more proposed locations, the market potential for renewable-energy sales, transmission and interconnection requirements at the one or more proposed locations, metering options, relative distances from a given proposed location to other locations or sites, relative distances from the given proposed location to a municipality or city, road access to the one or more proposed locations, information about the land slope or proximity to a river at the one or more proposed locations, obstructions to wind flow at the one or more proposed locations (such as a building or trees), vegetation (such as a plant height) at the one or more proposed locations, legal data (such as a regulatory ordinance and, more generally, rules and regulations associated with the one or more proposed locations), building or equipment incentives, industrial data, simulated data (such as data generated using a generative adversarial network), data associated with a database or data structure (e.g., a directed graph), and/or another type of data or information. In some embodiments, an image may be associated with a physical camera or imaging sensor. However, in other embodiments, an image may be associated with a ‘virtual camera’, such as an electronic device, computer or server that provides the image. Thus, the project-management techniques may be used to analyze images that have recently been acquired, to analyze images that are stored in the computer system and/or to analyze images received from one or more other electronic devices.

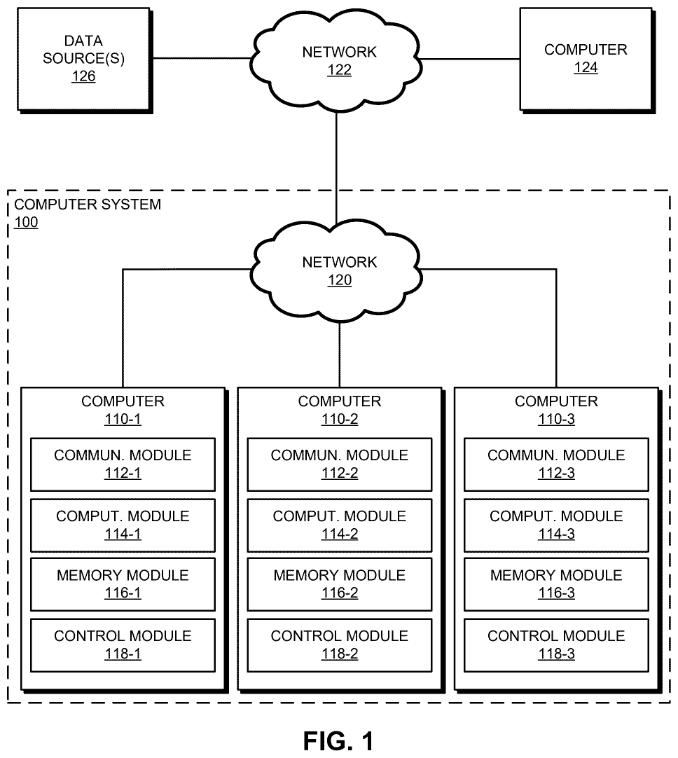

We now describe embodiments of the project-management techniques. FIG. 1 presents a block diagram illustrating an example of a computer system 100. This computer system may include one or more computers 110. These computers may include: communication modules 112, computation modules 114, memory modules 116, and optional control modules 118. Note that a given module or engine may be implemented in hardware and/or in software.

Communication modules 112 may communicate frames or packets with data or information (such as information used to generate and/or modify a plan for a power-system project, instructions for a pretrained neural network, or control instructions) between computers 110 via a network 120 (such as the Internet and/or an intranet). For example, this communication may use a wired communication protocol, such as an Institute of Electrical and Electronics Engineers (IEEE) 802.3 standard (which is sometimes referred to as ‘Ethernet’) and/or another type of wired interface. Alternatively or additionally, communication modules 112 may communicate the data or the information using a wireless communication protocol, such as: an IEEE 802.11 standard (which is sometimes referred to as ‘Wi-Fi’, from the Wi-Fi Alliance of Austin, Texas), Bluetooth (from the Bluetooth Special Interest Group of Kirkland, Washington), a third generation or 3G communication protocol, a fourth generation or 4G communication protocol, e.g., Long Term Evolution or LTE (from the 3rd Generation Partnership Project of Sophia Antipolis, Valbonne, France), LTE Advanced (LTE-A), a fifth generation or 5G communication protocol, other present or future developed advanced cellular communication protocol, or another type of wireless interface. For example, an IEEE 802.11 standard may include one or more of: IEEE 802.11a, IEEE 802.11b, IEEE 802.11g, IEEE 802.11-2007, IEEE 802.11n, IEEE 802.11-2012, IEEE 802.11-2016, IEEE 802.11ac, IEEE 802.11ax, IEEE 802.11ba, IEEE 802.11be, or other present or future developed IEEE 802.11 technologies.

In the described embodiments, processing a packet or a frame in a given one of computers 110 (such as computer 110-1) may include: receiving the signals with a packet or the frame; decoding/extracting the packet or the frame from the received signals to acquire the packet or the frame; and processing the packet or the frame to determine information contained in the payload of the packet or the frame. Note that the communication in FIG. 1 may be characterized by a variety of performance metrics, such as: a data rate for successful communication (which is sometimes referred to as ‘throughput’), an error rate (such as a retry or resend rate), a mean squared error of equalized signals relative to an equalization target, intersymbol interference, multipath interference, a signal-to-noise ratio, a width of an eye pattern, a ratio of number of bytes successfully communicated during a time interval (such as 1-10 s) to an estimated maximum number of bytes that can be communicated in the time interval (the latter of which is sometimes referred to as the ‘capacity’ of a communication channel or link), and/or a ratio of an actual data rate to an estimated data rate (which is sometimes referred to as ‘utilization’). Note that wireless communication between components in FIG. 1 uses one or more bands of frequencies, such as: 900 MHZ, 2.4 GHz, 5 GHZ, 6 GHz, 60 GHz, the Citizens Broadband Radio Spectrum or CBRS (e.g., a frequency band near 3.5 GHZ), and/or a band of frequencies used by LTE or another cellular-telephone communication protocol or a data communication protocol. In some embodiments, the communication between the components may use multi-user transmission (such as orthogonal frequency division multiple access or OFDMA) and/or multiple input multiple output (MIMO).

Moreover, computation modules 114 may perform calculations using: one or more microprocessors, ASICs, microcontrollers, programmable-logic devices, GPUs and/or one or more digital signal processors (DSPs). Note that a given computation component is sometimes referred to as a ‘computation device’.

Furthermore, memory modules 116 may access stored data or information in memory that is local in computer system 100 and/or that is remotely located from computer system 100. Notably, in some embodiments, one or more of memory modules 116 may access stored information in the local memory. Alternatively or additionally, in other embodiments, one or more memory modules 116 may access, via one or more of communication modules 112, stored information in the remote memory in computer 124, e.g., via network 120 and network 122. Note that network 122 may include: the Internet and/or an intranet. In some embodiments, the information may include data or information used to generate and/or modify a plan for a power-system project (which may be received from one or more data sources 126, such as cameras, environmental sensors, etc., via network 120 and network 122 and one or more of communication modules 112, and/or may specify one or more plans for power-system projects. Thus, in some embodiments at least some of the information may have been received previously and may be stored in memory, while in other embodiments at least some of the information may be received in real time from the one or more data sources 126 (e.g., as the plan for the power-system project is automatically generated or modified).

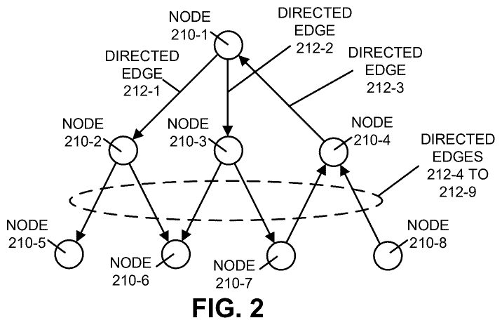

In some embodiments, information used to generate a plan for a power-system project or that specifies a plan for a power-system project (such as one or more parameters or values or parameters in the plan for the power-system project, e.g., an ROI, land cost, a loan amount, etc.) may be stored in a direct-graph data structure or database. FIG. 2 presents a drawing illustrating an example of a portion of a directed graph with a set of vertices or nodes 210 connected by directed edges 212 (which are sometimes referred to as ‘arcs’). In a directed-graph data structure or database, data is stored in the set of vertices or nodes 210 that have interrelationships (including directions) specified by directed edges 212.

While FIG. 1 illustrates computer system 100 at a particular location, in other embodiments at least a portion of computer system 100 is implemented at more than one location. Thus, in some embodiments, computer system 100 is implemented in a centralized manner, while in other embodiments at least a portion of computer system 100 is implemented in a distributed manner. For example, in some embodiments, the one or more data sources 126 may include local hardware and/or software that performs at least some of the operations in the power-management techniques. This remote processing may reduce the amount of information that is communicated via network 120 and network 122. In addition, the remote processing may anonymize the data that are communicated to and analyzed by computer system 100. This capability may help ensure computer system 100 is secure and maintains privacy.

Although we describe the computation environment shown in FIG. 1 as an example, in alternative embodiments, different numbers or types of components may be present in computer system 100. For example, some embodiments may include more or fewer components, a different component, and/or components may be combined into a single component, and/or a single component may be divided into two or more components. Alternatively or additionally, in some embodiments, some or all of the operations in the power-management techniques may be performed by an electronic device, such as a cellular telephone, a tablet, a computer, etc.

As discussed previously, it can be difficult to prepare plans for power-system projects and/or to obtain approval for these plans for projects with a cost of less than $2 M (such as distributed power-system projects). Moreover, as described further below with reference to FIGS. 2-10, in order to address these challenges computer system 100 may automate the generation and/or modifying of a plan for a power-system project. Notably, during the power-management techniques, one or more of optional control modules 118 may divide the generating and/or the modifying of the plan among computers 110. For example, the one or more of optional control modules 118 may obtain information from one or more of data sources 126 and/or in local and/or remote memory using one or more of memory modules 116. Alternatively, the one or more of optional control modules 118 may generate information (e.g., using another pretrained neural network).

Then, a given computer (such as computer 110-1) may perform at least a designated portion of generating and/or modifying the plan. Notably, computation module 114-1 may receive or access information (e.g., in local and/or remote memory using one or more of memory modules 116) that includes content used to generate and/or modify the plan, an architecture or configuration of the neural network (including a number of layers, a number of synapses, relationships or interconnections between synapses, activations functions, and/or weights), and/or a set of one or more hyperparameters governing at least the initial training of the neural network (such as a type or variation of stochastic gradient descent, a type of gradient, a learning rate or step size, e.g., 0.01, for the weights in a given layer in the neural network, a loss function, a regularizing term in a loss function, etc.). For example, the neural network may include a convolutional neural network with multiple layers. Each of the layers include one or more synapses. A given synapse may have associated weights and one or more activation functions (such as a rectified linear activation function or ReLU, ReLU6 in which the rectified linear activation function is modified to have a maximum size or value, a leaky ReLU, an exponential linear unit or ELU activation function, a parametric ReLU, a tanh activation function, or a sigmoid activation function) for each input to the given synapse. In general, the output of a given synapse of layer i may be fed as input into one or more synapse in layer i+1. Based at least in part on the information, computation module 114-1 may implement some or all of the pretrained neural network. Note that in some embodiments, the pretrained neural network may be a digital twin that provides a virtual representation of the power-system project.

One or more of computation modules 114 may implement the pretrained neural network based at least in part on the architecture or configuration of the neural network. Then, the one or more of computation modules 114 may provide, to the pretrained neural network, input information or content. In response, one or more of computation modules 114 may receive, from the pretrained neural network, an output with information (such as parameters) that specifies the plan or the modified plan for the power-system project.

For example, when generating the plan, the input information may include: wind data at one or more locations, solar data at one or more locations, weather conditions at one or more locations, ownership of land at one or more locations, energy cost, environmental conditions, connectivity, local infrastructure available at the one or more locations, regulations associated with a utility approval process for the at one or more locations, and available equipment (such as wind and/or solar equipment) that may be available at the one or more locations. In these embodiments, the output may include the parameters for the automatically generated plan.

Alternatively, when modifying an existing plan, the input information may include: the parameters for one or more plans (such as the existing plan and/or one or more plans for prior successful power-system projects); feedback about the existing plan (which may have been received during an approval process associated with a utility commission and/or a municipal government); an ordinance change (which may be associated with the municipal government or the regulator of a utility, such as a utility commission); and/or an estimated ROI of the power-system project. Moreover, in these embodiments, the output may include the parameters for the automatically modified plan. Note that the modified plan may decrease the estimated risk or increase an estimated probability of success of the power-system project (such as a probability that the power-system project achieves a goal, e.g., an estimated ROI). In some embodiments, one or more parameters in the updated or modified plan may be changed based at least in part on parameters associated with at least one of the prior power-system projects.

In some embodiments, computer system 100 may automatically submit (e.g., using one or more of communication modules 112) the plan or the modified plan during the approval process associated with the utility commission and/or the municipal government. Then, when the feedback is received (such as the feedback between at least a pair of steps in the approval process), computer system 100 may automatically update or modify the plan based at least in part on the received feedback, and may submit the updated or modified plan during the approval process. Thus, in some embodiments, computer system 100 may automatically and iteratively perform operations as the plan moves through the approval process, thereby significantly reducing the cost and/or time needed to obtain approval for the power-system project.

Note that the power-system project may have a cost that is less than a predefined amount. For example, the predefined amount may be $2 M. Moreover, a second cost of generating or modifying the plan may be less than a second predefined amount, such as 10% of the predefined amount. Moreover, the power-system project may include a distributed power-system project that is located at multiple locations in a region (as opposed to at a centralized location).

Furthermore, in some embodiments, computer system 100 may select or identify the power-system project. For example, one or more of computation modules 114 may compute an estimate of an ROI and/or a risk for the power-system project (such as a risk of not achieving the estimated ROI and, thus, of not being a successful project), and may select or identify the power-system project based at least in part on the estimated ROI and/or the estimated risk.

Alternatively or additionally, computer system 100 may: present the plans for the power-system projects and associated estimated risks and/or ROIs; and receive a user selection of the plan for the power-system project. For example, one or more of computation modules 114 may present the plans for the power-system projects and associated estimated risks and/or ROIs on a display (not shown) in or associated with computer system 100. Alternatively, one or more of communication modules 112 may provide instructions (e.g., to an electronic device of a user) for the plans for the power-system projects and associated estimated risks and/or ROIs. Then, the user may provide the user selection of the plan for the power-system project (e.g., using a user-interface device, such as a keyboard, a mouse, a track pad, a stylus, a touch-sensitive display, etc.).

After completing the generating and/or modifying of the plan, control module 118-1 may store results, e.g., the plan or the modified plan in local and/or remote memory using memory module 116-1. Alternatively or additionally, control module 118-1 may instruct communication module 114-1 to communicate results of the plan or the modified plan with other computers 110 in computer system 100 or with computers (not shown) external to computer system 100. This may allow the results from different computers 110 to be aggregated. In some embodiments, control module 118-1 may display or print out at least a portion of the results, e.g., to an operator of computer system 100, so that the operator can evaluate the plan or the modified plan.

In these ways, computer system 100 may improve the generating and/or modifying of the plan. For example, by automating the planning or the revision process, computer system 100 may significantly reduce the cost of generating and/or modifying the plan. Moreover, computer system 100 may employ learning from the plans for previous or prior successful power-system projects, thereby improving the current plan for the power-system project. Therefore, the power-management techniques may improve the financial impact (such as the ROI) and/or reduce the risk associated with the plan for the power-system project.

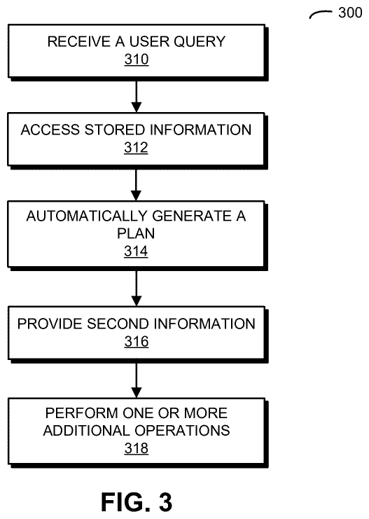

We now describe embodiments of the method. FIG. 3 presents a flow diagram illustrating an example of a method 300 for automatically generating a plan for a power-system project, which may be performed by a computer system (such as computer system 100 in FIG. 1). During operation, the computer system may receive a user query that specifies an objective or a goal (operation 310). Then, the computer system may access stored information (operation 312), where the stored information includes: wind data, solar data, ownership of land, energy cost, environmental conditions, connectivity, local infrastructure, regulations associated with a utility approval process, and/or available equipment (such as wind and/or solar equipment). Next, based at least in part on the information and the objective or goal, the computer system may automatically generate the plan (operation 314) for the power-system project. Moreover, the computer system may provide second information (operation 316) specifying the plan for the power-system project.

Note that the power-system project may have a cost that is less than a predefined amount. For example, the predefined amount may be $2 M. Moreover, a second cost of generating the plan may be less than a second predefined amount, such as 10% of the predefined amount.

Furthermore, the power-system project may include a distributed power-system project that is located at multiple locations in a region (as opposed to at a centralized location).

Additionally, the information may be accessed in a database, and the information may be stored in a directed graph.

Note that the plan may be generated using a pretrained LLM. More generally, the plan may be generated using a pretrained neural network. In some embodiments, the generating (operation 314) is performed using a digital twin that provides a virtual representation of the power-system project.

In some embodiments, the computer system may optionally perform one or more additional operations (operation 318). For example, the computer system may compute an estimate of an ROI for the power-system project, and the computer system may select the power-system project based at least in part on the estimated ROI.

Moreover, the computer system may determine an estimated risk associated with the power-system project, and the computer system selects the power-system project based at least in part on the estimated risk.

Furthermore, providing the second information (operation 316) may include: storing the second information in a computer-readable memory; displaying the second information on a display; and/or printing the second information on paper.

Additionally, automatically generating the plan (operation 314) may include submitting the plan and receiving feedback about the plan during an approval process associated with a regulator of a utility or a power system and/or a municipal government, and, as needed, automatically and iteratively updating the plan based at least in part on the feedback between at least a pair of steps in the approval process.

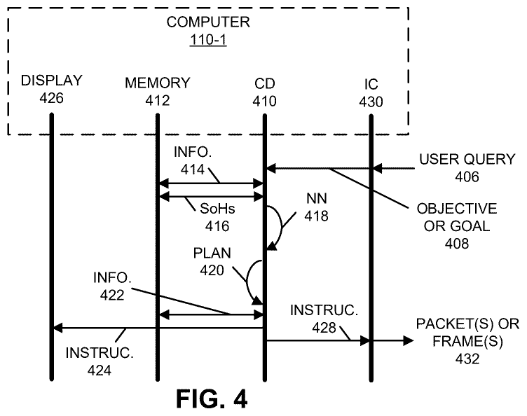

Embodiments of the power-management techniques are further illustrated in FIG. 4, which presents a drawing illustrating an example of communication among components in computer system 100. In FIG. 4, an interface circuit (IC) 430 in computer 110-1 may receive a user query 406, e.g., from an electronic device (not shown) associated with a user of computer 110-1, that specifies an objective or a goal 408 (such as providing a particular amount of power while reducing associated carbon emissions relative to existing power systems). This objective or goal 408 is provided to a computation device (CD) 410 (such as a processor or a GPU) in computer 110-1.

Then, computation device 410 may access in memory 412 in computer 110-1 information 414 specifying: wind data, solar data, ownership of land, energy cost, environmental conditions, connectivity, local infrastructure, regulations associated with a utility approval process, and/or available equipment (such as wind and/or solar equipment). Moreover, computation device 410 may access, in memory 412, a set of one or more hyperparameters 416 (SoHs) and an architecture or a configuration of a neural network (NN) 418. Based at least in part on the one or more hyperparameters 416 (SoHs) and the architecture or the configuration, computation device 410 may implement the neural network 418.

Next, based at least in part on information 414 and objective or goal 408, and using neural network 418, computation device 410 may automatically generate a plan 420 for a power-system project. Because plan 420 s generated based at least in part on objective or goal 408, computer system 400 may dynamically adapt or respond to different user queries (such as user query 406).

After or while generating plan 420, computation device 410 may store results (such as information 422) in memory 412. Alternatively or additionally, computation device 410 may provide instructions 424 to a display 426 in computer 110-1 to display information 422. In some embodiments, computation device 410 may provide instructions 428 to interface circuit 430 to provide one or more packets or frames 432 with information 422 to another computer or electronic device (not shown) and/or a printer (not shown). For example, the other computer or electronic device may be associated with the user of computer system 100.

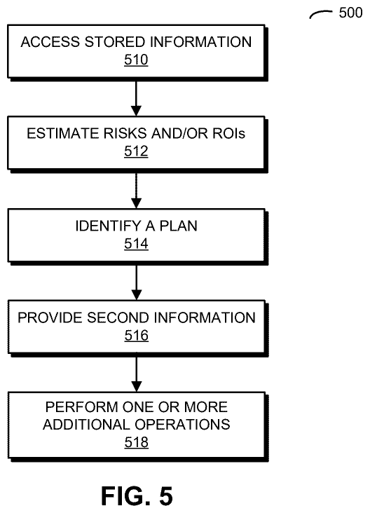

FIG. 5 presents a flow diagram illustrating an example of a method 500 for identifying a plan for a power-system project, which may be performed by a computer system (such as computer system 100 in FIG. 1). During operation, the computer system may access stored information (operation 510) that specifies plans for power-system projects. Then, based at least in part on the information, the computer system may estimate risks and/or ROIs (operation 512) for the power-system projects. Moreover, based at least in part on the estimated risks and/or ROIs, the computer system may identify the plan (operation 514) for the power-system project in the plans for the power-system projects. Next, the computer system may provide second information (operation 516) specifying the identified plan for the power-system project.

Note that the power-system project may have a cost that is less than a predefined amount. For example, the predefined amount may be $2 M.

Moreover, the power-system project may include a distributed power-system project that is located at multiple locations in a region (as opposed to at a centralized location).

Furthermore, the information may be accessed in a database, and the information may be stored in a directed graph.

In some embodiments, the computer system may optionally perform one or more additional operations (operation 518). For example, based at least in part on an ordinance change associated with a municipal government or a regulator of a utility, the computer system may automatically modify the plan for the power system project, where the modified plan decreases an estimated risk of the power-system project and/or increases an estimated ROI of the power-system project. Note that the plan may be modified using a pretrained LLM. More generally, the plan may be modified using a pretrained neural network. In some embodiments, the modifying is performed using a digital twin that provides a virtual representation of the power-system project.

Moreover, providing the second information (operation 516) may include: storing the second information in a computer-readable memory; displaying the second information on a display; and/or printing the second information on paper.

Furthermore, the computer system may automatically submit the identified plan and receive feedback about the plan during an approval process associated with a utility commission and/or a municipal government. As needed, the computer system may automatically and iteratively update the plan based at least in part on the feedback between at least a pair of steps in the approval process.

Additionally, identifying the plan (operation 514) may include: presenting the plans for the power-system projects and associated estimated risks and/or ROIs; and receiving a user selection of the plan for the power-system project. Alternatively, the computer system may automatically identify the plan.

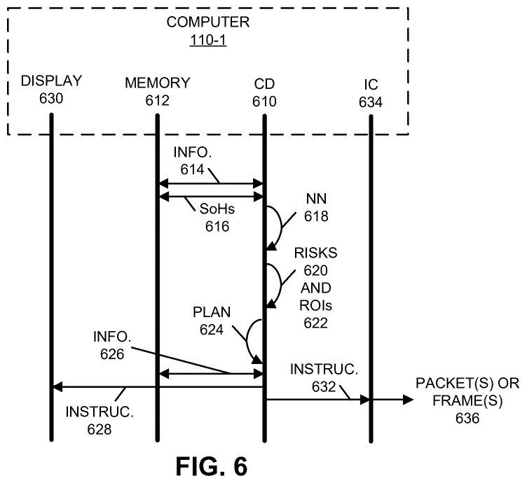

Embodiments of the power-management techniques are further illustrated in FIG. 6, which presents a drawing illustrating an example of communication among components in computer system 100. In FIG. 6, a computation device (CD) 610 (such as a processor or a GPU) in computer 110-1 may access in memory 612 in computer 110-1 information 614 specifying plans for power-system projects. Moreover, computation device 610 may access, in memory 612, include a set of one or more hyperparameters 616 (SoHs) and an architecture or a configuration of a neural network (NN) 418. Based at least in part on the one or more hyperparameters 616 (SoHs) and the architecture or the configuration, computation device 610 may implement the neural network 618.

Then, based at least in part on information 614, computation device 610 may estimate risks 620 and/or ROIs 622 for the power-system projects. Moreover, based at least in part on the estimated risks 620 and/or ROIs 622, computation device 610 may identify a plan 624 for the power-system project in the plans for the power-system projects. For example, computation device 610 may select plan 624 with the lowest estimated risk and/or the highest ROI (e.g., during a time interval, such as a next 3 or 5 years). In some embodiments, computation device 610 may estimate risks 620 and/or ROIs 622 for the power-system projects, and/or may select plan 624 using neural network 618.

After or while selecting plan 624, computation device 410 may store information 626 specifying plan 624 in memory 412. Alternatively or additionally, computation device 610 may provide instructions 628 to a display 630 in computer 110-1 to display information 626. In some embodiments, computation device 410 may provide instructions 632 to an interface circuit (IC) 634 in computer 110-1 to provide one or more packets or frames 636 with information 626 to another computer or electronic device (not shown) and/or a printer (not shown). For example, the other computer or electronic device may be associated with a user of computer system 100.

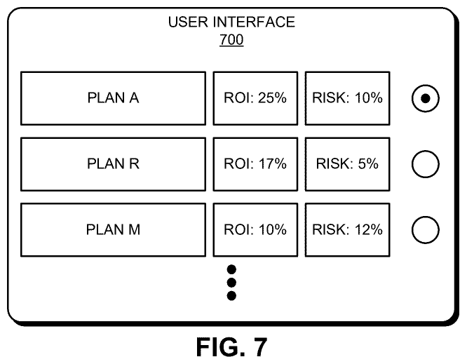

FIG. 7 presents a drawing illustrating an example of a user interface 700 associated with a computer 110-1 in FIG. 1. For example, user interface 700 may be displayed on a display in or associated with computer 110-1.

During operation, computer 110-1 may display plans for the power-system projects and associated estimated risks and/or ROIs. In response, a user of computer 110-1 may select one of the plans for a power-system project by providing a user selection using a user-interface device. In this way, computer 110-1 may identify the plan.

In some embodiments, user interface 700 may include additional or fewer user-interface objects or components. Moreover, the positions of one or more of the user-interface objects or components may be changed, a different user-interface object or component may be used (such as a slider, a radio button, a check box, a text entry box, etc.), two or more of the user-interface objects or components may be combined into a single user-interface object or component, and/or a single user-interface object or component may be divided into two or more user-interface objects or components.

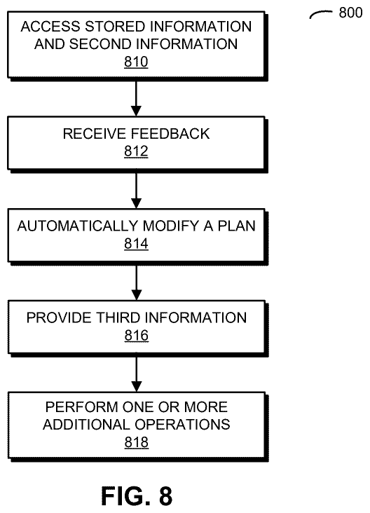

FIG. 8 presents a flow diagram illustrating an example of a method 800 for modifying a plan for a power-system project, which may be performed by a computer system (such as computer system 100 in FIG. 1). During operation, the computer system may access stored information (operation 810) that specifies the plan for the power-system project and second information specifying prior power-system projects that were successful. Then, the computer system may submit the plan and receive feedback about the plan (operation 812) during an approval process associated with a utility commission and/or a municipal government. Moreover, based at least in part on the second information and the feedback, the computer system may automatically modify the plan (operation 814) for the power-system project, where the modified plan increases an estimated probability of success of the power-system project. Next, the computer system may provide third information (operation 816) specifying the modified plan for the power-system project.

Note that the power-system project may have a cost that is less than a predefined amount. For example, the predefined amount may be $2 M.

Moreover, the power-system project may include a distributed power-system project that is located at multiple locations in a region (as opposed to at a centralized location).

Furthermore, the information and/or the second information may be accessed in a database, and the information may be stored in a directed graph.

Note that modifying the plan may include changing one or more parameters in the plan based at least in part on parameters associated with at least one of the prior power-system projects.

In some embodiments, the computer system may optionally perform one or more additional operations (operation 818). For example, the computer system may compute an estimate of an ROI for the power-system project, and the plan may be modified (operation 814) based at least in part on the estimated ROI. Note that the plan may be modified using a pretrained LLM. More generally, the plan may be modified using a pretrained neural network. In some embodiments, the modifying is performed using a digital twin that provides a virtual representation of the power-system project.

Moreover, the computer system may determine an estimated risk associated with the power-system project, and the plan may be modified (operation 814) based at least in part on the estimated risk.

Furthermore, providing the third information (operation 816) may include: storing the third information in a computer-readable memory; displaying the third information on a display; and/or printing the third information on paper.

In some embodiments of method 300 (FIG. 3), 500 (FIG. 5) and/or 800, there may be additional or fewer operations. Furthermore, the order of the operations may be changed, and/or two or more operations may be combined into a single operation.

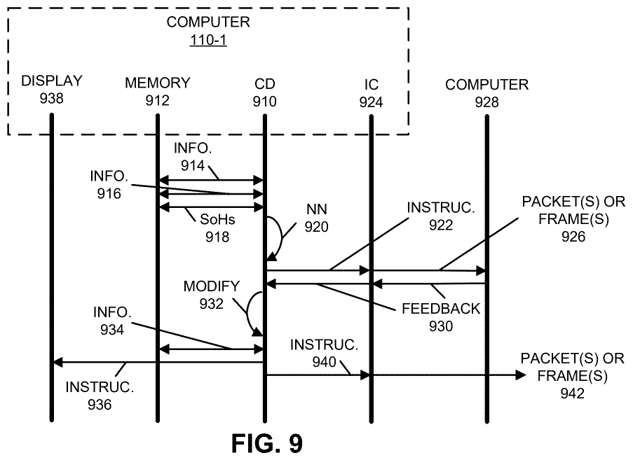

Embodiments of the power-management techniques are further illustrated in FIG. 9, which presents a drawing illustrating an example of communication among components in computer system 100. In FIG. 9, a computation device (CD) 910 (such as a processor or a GPU) in computer 110-1 may access in memory 912 in computer 110-1 information 914 that specifies a plan for a power-system project and information 916 specifying prior power-system projects that were successful. Moreover, computation device 910 may access, in memory 912, a set of one or more hyperparameters 918 (SoHs) and an architecture or a configuration of a neural network (NN) 920. Based at least in part on the one or more hyperparameters 918 (SoHs) and the architecture or the configuration, computation device 910 may implement the neural network 920.

Then, computation device 910 may instruct 922 an interface circuit (IC) 924 in computer 110-1 to submit, as part of an approval process, the plan (e.g., in one or more packets or frames 926) to a computer 928 associated with a utility commission and/or a municipal government. In response, computer 928 may subsequently provide feedback 930 about the plan to computer 110-1.

After receiving feedback 930, interface circuit 926 may provide feedback 930 to computation device 910. In response, based at least in part on information 916 and feedback 930, and using neural network 920, computation device 910 may automatically modify 932 the plan for the power-system project, where the modified plan increases an estimated probability of success of the power-system project.

After or while modifying the plan, computation device 910 may store results (such as information 934) in memory 912. Alternatively or additionally, computation device 910 may provide instructions 936 to a display 938 in computer 110-1 to display the results. In some embodiments, computation device 910 may provide instructions 940 to interface circuit 924 to provide one or more packets or frames 942 with information 934 to another computer or electronic device (not shown) and/or a printer (not shown). For example, the other computer or electronic device may be associated with a user of computer system 100.

While FIGS. 4, 6 and 9 illustrate communication between components using unidirectional or bidirectional communication with lines having single arrows or double arrows, in general the communication in a given operation in these figures may involve unidirectional or bidirectional communication.

We now further describe embodiments of the power-management techniques. Energy manufacturing projects are typically handled with the same rigorous criteria regarding the project size and/or the hardware/software platform that is to be used. Consequently, plans for solar or wind farms are handled in the same way as plans for nuclear power plants.

As we think about power distribution and the ability to move power generation sources closer to the users, there is a problem when the funding and program management cost more than the expense of building the power plant.

Therefore, there is a need for a clearinghouse or renewable energy management platform (or service) to cut by the time and cost needed by 90% or more, while still putting the smaller-scale power project through the same level of due diligence that is typical and understandable in utility-scale energy projects.

The disclosed project-management techniques enable the development phase of any projects value chain, from origination (ORI) to final investment decision (FID), using simulations (such as using a digital twin). Notably, the disclosed computer system may provide a single platform for managing development projects from origination (greenfield, brownfield, through co-development, acquisition, or tender) to FID. The computer system may allow the involved parties to contribute and/or view project information, and to efficiently collaborate throughout the development process.

The computer system may include or may provide: a renewable-energy digital twin; an agnostic system allows OEMs to upload equipment specifications, eventually allowing developers to run different production scenarios; and a proprietary rating engine to enable scoring of plans for power-system projects that may be used to aggregate and to securitize or crowdfund. Note that the platform may be designed specifically for the energy investor segment of any kind. This means that while power-system projects are being developed or considered for acquisitions by FinEnt and managed by power distributors or utilities, the platform may provide active learning and/or feedback to simulate and visualize scenarios in real-time.

The disclosed platform may use or may include: directed graph-based databases; LLMs; physical and/or digital proof models; and/or unique and a real-time trust-based rating model.

In the automatic power-system-project plan generation embodiments, the platform may include or may provide: a renewable-energy digital twin risk assessment system.

Moreover, in the discovery or identification of power-system-project plan embodiments, the platform may be used to discover and rate power-system-project opportunities. These opportunities may allow resources to be repurposed to build new micro-power plants. For example, a renewable-energy digital twin may be used to discover and optionally rate opportunities to repurpose resources to build micro power plants.

Furthermore, in the power-system plan modification embodiments, the platform may include learning (such as using a supervised-learning technique) to accelerate the power-system approval process and power-system-project success. Notably, by identifying which plans for power-system projects are approved and successful, the platform may adjust or modify the parameters in the power-system-project plans based at least in part on received feedback to increase the probability that the plan will be approved and will be successful (e.g., in achieving estimated ROI). For example, a renewable-energy digital twin with supervised learning may modify the plan for a power-system project based at least in part on feedback received in an approval process and parameters of at least a prior successful power-system project (which may have been created using the same platform). Note that a successful power-system project may achieve an estimated milestone (such as being within 10 or 25% of an estimated ROI) with 3 or 6 mo. of a target time interval (such as 3 or 5 years). In some embodiments, the supervised-learning technique may include a machine-learning model that is based at least in part on a trust-based model. Note that the supervised-learning technique may include: a support vector machine technique, a classification and regression tree technique, logistic regression, LASSO, linear regression, a neural network technique (such as a convolutional neural network technique, a long short-term memory or LSTM neural network technique, an autoencoder neural network or another type of neural network technique) and/or another linear or nonlinear supervised-learning technique.

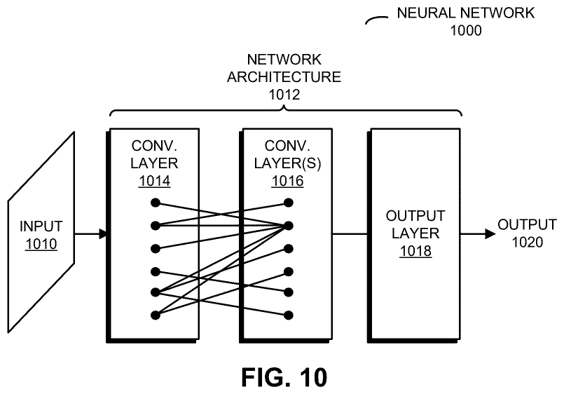

FIG. 10 presents a block diagram illustrating an example of a neural network 1000. Notably, neural network 1000 may be implemented using a convolutional neural network. This neural network may include a network architecture 1012 that includes: an initial convolutional layer 1014 that provides filtering of image 1010; one or more additional convolutional layer(s) 1016 that apply weights; and an output layer 1018 (such as a rectified linear layer) that performs classification (e.g., distinguishing a dog from a cat) and provides output 1020. Note that the details with the different layers in neural network 1000, as well as their interconnections, may define network architecture 1012 (such as a directed acyclic graph). These details may be specified by the instructions for neural network 1000. In some embodiments, neural network 1000 may be reformulated as a series of matrix multiplication operations.

Note that neural network 1000 may be used to analyze inputs (such as inputs 1010).

In some embodiments, the power-management techniques are used to identify one or more candidate project locations and to automatically generate one or more plans for one or more power-system projects in response to a user query that specifies an objective or a goal. For example, the objective or the goal may include providing an amount of power while reducing the associated carbon emissions of a utility or a power provider by a corresponding amount.

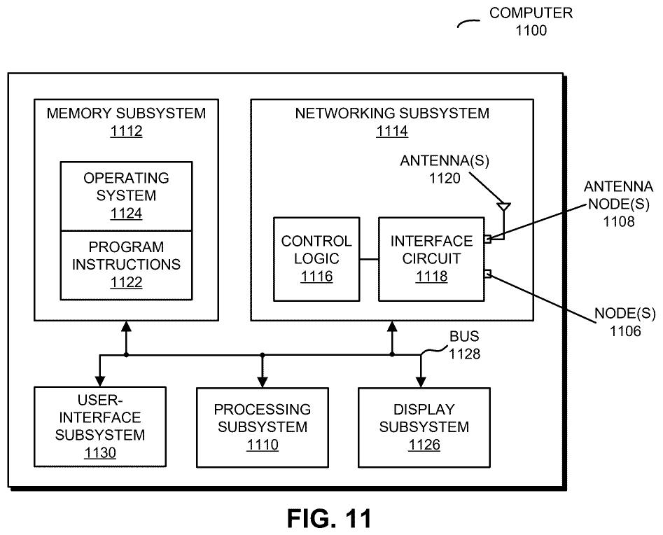

We now describe embodiments of a computer, which may perform at least some of the operations in the power-management techniques. FIG. 11 presents a block diagram illustrating an example of a computer 1100, e.g., in a computer system (such as computer system 100 in FIG. 1), in accordance with some embodiments. For example, computer 1100 may include: one of computers 110. This computer may include processing subsystem 1110, memory subsystem 1112, and networking subsystem 1114. Processing subsystem 1110 includes one or more devices configured to perform computational operations. For example, processing subsystem 1110 can include one or more microprocessors, ASICs, microcontrollers, programmable-logic devices, GPUs and/or one or more DSPs. Note that a given component in processing subsystem 1110 are sometimes referred to as a ‘computation device’.

Memory subsystem 1112 includes one or more devices for storing data and/or instructions for processing subsystem 1110 and networking subsystem 1114. For example, memory subsystem 1112 can include dynamic random access memory (DRAM), static random access memory (SRAM), and/or other types of memory. In some embodiments, instructions for processing subsystem 1110 in memory subsystem 1112 include: program instructions or sets of instructions (such as program instructions 1122 or operating system 1124), which may be executed by processing subsystem 1110. Note that the one or more computer programs or program instructions may constitute a computer-program mechanism. Moreover, instructions in the various program instructions in memory subsystem 1112 may be implemented in: a high-level procedural language, an object-oriented programming language, and/or in an assembly or machine language. Furthermore, the programming language may be compiled or interpreted, e.g., configurable or configured (which may be used interchangeably in this discussion), to be executed by processing subsystem 1110.

In addition, memory subsystem 1112 can include mechanisms for controlling access to the memory. In some embodiments, memory subsystem 1112 includes a memory hierarchy that comprises one or more caches coupled to a memory in computer 1100. In some of these embodiments, one or more of the caches is located in processing subsystem 1110.

In some embodiments, memory subsystem 1112 is coupled to one or more high-capacity mass-storage devices (not shown). For example, memory subsystem 1112 can be coupled to a magnetic or optical drive, a solid-state drive, or another type of mass-storage device. In these embodiments, memory subsystem 1112 can be used by computer 1100 as fast-access storage for often-used data, while the mass-storage device is used to store less frequently used data.

Networking subsystem 1114 includes one or more devices configured to couple to and communicate on a wired and/or wireless network (i.e., to perform network operations), including: control logic 1116, an interface circuit 1118 and one or more antennas 1120 (or antenna elements). (While FIG. 11 includes one or more antennas 1120, in some embodiments computer 1100 includes one or more nodes, such as antenna nodes 1108, e.g., a metal pad or a connector, which can be coupled to the one or more antennas 1120, or nodes 1106, which can be coupled to a wired or optical connection or link. Thus, computer 1100 may or may not include the one or more antennas 1120. Note that the one or more nodes 1106 and/or antenna nodes 1108 may constitute input(s) to and/or output(s) from computer 1100.) For example, networking subsystem 1114 can include a Bluetooth™ networking system, a cellular networking system (e.g., a 3G/4G/5G network such as UMTS, LTE, etc.), a universal serial bus (USB) networking system, a networking system based on the standards described in IEEE 802.11 (e.g., a Wi-Fi® networking system), an Ethernet networking system, and/or another networking system.

Networking subsystem 1114 includes processors, controllers, radios/antennas, sockets/plugs, and/or other devices used for coupling to, communicating on, and handling data and events for each supported networking system. Note that mechanisms used for coupling to, communicating on, and handling data and events on the network for each network system are sometimes collectively referred to as a ‘network interface’ for the network system. Moreover, in some embodiments a ‘network’ or a ‘connection’ between the electronic devices does not yet exist. Therefore, computer 1100 may use the mechanisms in networking subsystem 1114 for performing simple wireless communication between electronic devices, e.g., transmitting advertising or beacon frames and/or scanning for advertising frames transmitted by other electronic devices.

Within computer 1100, processing subsystem 1110, memory subsystem 1112, and networking subsystem 1114 are coupled together using bus 1128. Bus 1128 may include an electrical, optical, and/or electro-optical connection that the subsystems can use to communicate commands and data among one another. Although only one bus 1128 is shown for clarity, different embodiments can include a different number or configuration of electrical, optical, and/or electro-optical connections among the subsystems.

In some embodiments, computer 1100 includes a display subsystem 1126 for displaying information on a display, which may include a display driver and the display, such as a liquid-crystal display, a multi-touch touchscreen, etc. Moreover, computer 1100 may include a user-interface subsystem 1130, such as: a mouse, a keyboard, a trackpad, a stylus, a voice-recognition interface, and/or another human-machine interface.

Computer 1100 can be (or can be included in) any electronic device with at least one network interface. For example, computer 1100 can be (or can be included in): a desktop computer, a laptop computer, a subnotebook/netbook, a server, a supercomputer, a tablet computer, a smartphone, a cellular telephone, a consumer-electronic device, a portable computing device, communication equipment, and/or another electronic device.

Although specific components are used to describe computer 1100, in alternative embodiments, different components and/or subsystems may be present in computer 1100. For example, computer 1100 may include one or more additional processing subsystems, memory subsystems, networking subsystems, and/or display subsystems. Additionally, one or more of the subsystems may not be present in computer 1100. Moreover, in some embodiments, computer 1100 may include one or more additional subsystems that are not shown in FIG. 11. Also, although separate subsystems are shown in FIG. 11, in some embodiments some or all of a given subsystem or component can be integrated into one or more of the other subsystems or component(s) in computer 1100. For example, in some embodiments program instructions 1122 are included in operating system 1124 and/or control logic 1116 is included in interface circuit 1118.

Moreover, the circuits and components in computer 1100 may be implemented using any combination of analog and/or digital circuitry, including: bipolar, PMOS and/or NMOS gates or transistors. Furthermore, signals in these embodiments may include digital signals that have approximately discrete values and/or analog signals that have continuous values. Additionally, components and circuits may be single-ended or differential, and power supplies may be unipolar or bipolar.

An integrated circuit may implement some or all of the functionality of networking subsystem 1114 and/or computer 1100. The integrated circuit may include hardware and/or software mechanisms that are used for transmitting signals from computer 1100 and receiving signals at computer 1100 from other electronic devices. Aside from the mechanisms herein described, radios are generally known in the art and hence are not described in detail. In general, networking subsystem 1114 and/or the integrated circuit may include one or more radios.

In some embodiments, an output of a process for designing the integrated circuit, or a portion of the integrated circuit, which includes one or more of the circuits described herein may be a computer-readable medium such as, for example, a magnetic tape or an optical or magnetic disk or solid state disk. The computer-readable medium may be encoded with data structures or other information describing circuitry that may be physically instantiated as the integrated circuit or the portion of the integrated circuit. Although various formats may be used for such encoding, these data structures are commonly written in: Caltech Intermediate Format (CIF), Calma GDS II Stream Format (GDSII), Electronic Design Interchange Format (EDIF), OpenAccess (OA), or Open Artwork System Interchange Standard (OASIS). Those of skill in the art of integrated circuit design can develop such data structures from schematics of the type detailed above and the corresponding descriptions and encode the data structures on the computer-readable medium. Those of skill in the art of integrated circuit fabrication can use such encoded data to fabricate integrated circuits that include one or more of the circuits described herein.

While some of the operations in the preceding embodiments were implemented in hardware or software, in general the operations in the preceding embodiments can be implemented in a wide variety of configurations and architectures. Therefore, some or all of the operations in the preceding embodiments may be performed in hardware and/or in software. For example, at least some of the operations in the power-management techniques may be implemented using program instructions 1122, operating system 1124 (such as a driver for interface circuit 1118) or in firmware in interface circuit 1118. Thus, the power-management techniques may be implemented at runtime of program instructions 1122. Alternatively or additionally, at least some of the operations in the power-management techniques may be implemented in a physical layer, such as hardware in interface circuit 1118.

In the preceding description, we refer to ‘some embodiments’. Note that ‘some embodiments’ describes a subset of all of the possible embodiments, but does not always specify the same subset of embodiments. Moreover, note that the numerical values provided are intended as illustrations of the power-management techniques. In other embodiments, the numerical values can be modified or changed.

The foregoing description is intended to enable any person skilled in the art to make and use the disclosure, and is provided in the context of a particular application and its requirements. Moreover, the foregoing descriptions of embodiments of the present disclosure have been presented for purposes of illustration and description only. They are not intended to be exhaustive or to limit the present disclosure to the forms disclosed. Accordingly, many modifications and variations will be apparent to practitioners skilled in the art, and the general principles defined herein may be applied to other embodiments and applications without departing from the spirit and scope of the present disclosure. Additionally, the discussion of the preceding embodiments is not intended to limit the present disclosure. Thus, the present disclosure is not intended to be limited to the embodiments shown, but is to be accorded the widest scope consistent with the principles and features disclosed herein.

What is claimed is:

1. A computer system, comprising:
a computation device;
memory configured to store program instructions, wherein, when executed by the computation device, the program instructions cause the computer system to perform one or more operations comprising:
accessing stored information that specifies plans for power-system projects;
based at least in part on the information, estimating risks, return on investments (ROIs) or both for the power-system projects;
based at least in part on the estimated risks, ROIs or both, identifying a plan for a power-system project in the plans for the power-system projects; and
providing second information specifying the identified plan for the power-system project.

2. The computer system of claim 1, wherein the power-system project has a cost that is less than a predefined amount.

3. The computer system of claim 2, wherein the predefined amount comprises $2 M.

4. The computer system of claim 1, wherein the power-system project comprises a distributed power-system project that is located at multiple locations in a region.

5. The computer system of claim 1, wherein the information is accessed in a database, and the information is stored in a directed graph.

6. The computer system of claim 1, wherein the operations comprise, based at least in part on an ordinance change associated with a municipal government or a regulator of a utility, the operations comprise automatically modifying the plan for the power system project; and
wherein the modified plan decreases an estimated risk of the power-system project, increases an estimated ROI of the power-system project, or both.

7. The computer system of claim 1, wherein the plan is generated using a pretrained large-language model (LLM).

8. The computer system of claim 1, wherein the modifying is performed using a digital twin that provides a virtual representation of the power-system project.

9. The computer system of claim 1, wherein providing the second information comprises: storing the second information in a computer-readable memory; displaying the second information on a display; and/or printing the second information on paper.

10. The computer system of claim 1, wherein the operation comprise:
submitting the plan and receiving feedback about the plan during an approval process associated with a utility commission and/or a municipal government; and
automatically and iteratively updating the plan based at least in part on the feedback between at least a pair of steps in the approval process.

11. The computer system of claim 1, wherein identifying the plan comprises:
presenting the plans for the power-system projects and associated estimated risks, ROIs or both; and
receiving a user selection of the plan for the power-system project.

12. A non-transitory computer-readable storage medium for use in conjunction with a computer system, the computer-readable storage medium storing program instructions that, when executed by the computer system, cause the computer system to perform operations comprising:
accessing stored information that specifies plans for power-system projects;
based at least in part on the information, estimating risks, return on investments (ROIs) or both for the power-system projects;
based at least in part on the estimated risks, ROIs or both, identifying a plan for a power-system project in the plans for the power-system projects; and
providing second information specifying the identified plan for the power-system project.

13. The non-transitory computer-readable storage medium of claim 12, wherein the power-system project has a cost that is less than a predefined amount; and
wherein the predefined amount comprises $2 M.

14. The non-transitory computer-readable storage medium of claim 12, wherein the power-system project comprises a distributed power-system project that is located at multiple locations in a region.

15. The non-transitory computer-readable storage medium of claim 12, wherein the operations comprise, based at least in part on an ordinance change associated with a municipal government or a regulator of a utility, the operations comprise automatically modifying the plan for the power system project; and
wherein the modified plan decreases an estimated risk of the power-system project, increases an estimated ROI of the power-system project, or both.

16. A method for identifying a plan for a power-system project, comprising:
by a computer system:
accessing stored information that specifies plans for power-system projects;
based at least in part on the information, estimating risks, return on investments (ROIs) or both for the power-system projects;
based at least in part on the estimated risks, ROIs or both, identifying the plan for the power-system project in the plans for the power-system projects; and
providing second information specifying the identified plan for the power-system project.

17. The method of claim 16, wherein the power-system project has a cost that is less than a predefined amount; and
wherein the predefined amount comprises $2 M.

18. The method of claim 16, wherein the power-system project comprises a distributed power-system project that is located at multiple locations in a region.

19. The method of claim 16, wherein the method comprises, based at least in part on an ordinance change associated with a municipal government or a regulator of a utility, the operations comprise automatically modifying the plan for the power system project; and
wherein the modified plan decreases an estimated risk of the power-system project, increases an estimated ROI of the power-system project, or both.

20. The method of claim 16, wherein the modifying is performed using a digital twin that provides a virtual representation of the power-system project.
